(19) United States
(12) Patent Application Publication
(10) Pub. No.: US 2025/0079214 A1
(43) Pub. Date: Mar. 6, 2025

(54) THREE-SIDE CONVEYOR EQUIPMENT FOR SILICON WAFERS

(71) Applicant: TCL ZHONGHUAN RENEWABLE ENERGY TECHNOLOGY CO., LTD., Tianjin (CN)

(72) Inventors: Mengcheng QU, Tianjin (CN); Rui WU, Tianjin (CN); Dawei BAI, Tianjin (CN); Zhijun WU, Tianjin (CN); Zhengmin CAO, Tianjin (CN); Ruipeng LI, TianJin (CN); Dawei WANG, Tianjin (CN); Yao WAN, Tianjin (CN); Xianzheng YIN, Tianjin (CN); Chen YANG, Tianjin (CN)

(73) Assignee: TCL ZHONGHUAN RENEWABLE ENERGY TECHNOLOGY CO., LTD., Tianjin (CN)

(21) Appl. No.: 18/555,525

(22) PCT Filed: Jul. 31, 2023
(86) PCT No.: PCT/CN2023/110425

§ 371 Date: Oct. 15, 2023

(30) Foreign Application Priority Data
Oct. 27, 2022 (CN) 202222842699.9

(51) Int. Cl. H01L 21/677

(52) U.S. Cl. CPC H01L 21/67706

(57) ABSTRACT

A three-side conveyor equipment for silicon wafers is provided, including an insertion container. A bottom conveyor belt and two side conveyor belts are arranged in the insertion container, the two side conveyor belts are arranged opposite to each other above the bottom conveyor belt, the bottom conveyor belt is connected to the side conveyor belts through a transmission assembly, and a linear speed of the bottom conveyor belt is same as a linear speed of each of the side conveyor belts, and each of the side conveyor belts is arranged on a movable bracket that drives the side conveyor belt to clamp or loosen, and the insertion container is provided with two pushing assemblies that respectively push the two movable brackets to move. The two side conveyor belts can clamp or loosen the silicon wafers, and at the same time maintain a same linear speed as the bottom conveyor belt.

### CROSS-REFERENCE TO RELATED APPLICATION

This application claims priority to and the benefit of Chinese Patent Application No. 202222842699.9, filed in the China National Intellectual Property Administration on Oct. 27, 2022, the disclosure of which is hereby incorporated by reference in its entirety.

### FIELD OF DISCLOSURE

The present disclosure relates to a field of a conveyor equipment for silicon wafer and in particular, to a three-side conveyor equipment for silicon wafers.

### DESCRIPTION OF RELATED ART

In an insertion container, silicon wafers need to be attached to an insertion belt to be inserted smoothly. Before being attached, all silicon wafers need to be sent to the insertion belt. It requires a three-side conveyor to transport nearly 4,000 silicon wafers at the same time. In the three-side conveyor, if a conveyor belt at any side has a different speed from another conveyor belt, it easily causes the silicon wafers to skew and affects the close attachment of the silicon wafer to the insertion belt. If the speeds of the conveyor belts differ significantly, the silicon wafers can be squeezed between each other to potentially break the silicon wafers during transport.

The publication number CN 204384268, titled anti-jamming three-side synchronous conveyer belt, discloses a transmission structure for three-side synchronous conveying. In this transmission structure, conveyor belts at two sides cannot move. However, in an automatic silicon wafer production line, the conveyor belt needs to tightly clamp silicon wafers for transport, then release the silicon wafers for a next procedure.

### SUMMARY

It is an objective for the present disclosure to provide a three-side conveyor equipment for silicon wafers.

The present disclosure is creative in that two side conveyor belts can clamp or loosen silicon wafers, and maintain a same linear speed as a bottom conveyor belt.

Accordingly, the present disclosure provides:

A three-side conveyor equipment for silicon wafers, including: an insertion container, wherein a bottom conveyor belt and two side conveyor belts are disposed in the insertion container, the two side conveyor belts are arranged opposite to each other above the bottom conveyor belt, the bottom conveyor belt is connected to the side conveyor belts through a transmission assembly, a linear speed of the bottom conveyor belt is same as a linear speed of each of the side conveyor belts, each of the side conveyor belts is arranged on a movable bracket that drives the side conveyor belt to clamp or loosen, and the insertion container is provided with two pushing assemblies that respectively push the two movable brackets to move.

The silicon wafers are placed on the bottom conveyor belt, and the pushing assemblies push the two movable brackets to move. The side conveyor belt clamps and moves towards the silicon wafer to clamp the silicon wafer. A driving assembly drives the transmission assembly to rotate. The bottom conveyor belt and the side conveyor belt rotates synchronously to send the silicon wafer to an insertion belt. The pushing assemblies retract, and the side conveyor belt releases the silicon wafer.

In some embodiment of the present disclosure, the transmission assembly includes a first rotation shaft disposed on each of the side conveyor belts and a second rotation shaft disposed on the bottom conveyor belt, a transitional bevel gear is disposed at each of two ends of the second rotation shaft, a driven spur gear is disposed on each of the first rotation shafts, two third rotation shafts are arranged on the insertion container, a driven bevel gear is meshed with each of the transitional bevel gears and is disposed at a bottom of each of the third rotation shafts, a driving spur gear is disposed at a top of each of the third rotation shafts, and each of the driving spur gears is connected to a corresponding one of the driven spur gears by a connection belt. The transition bevel gear is meshed with the driven bevel gear to transmit the rotation of the second rotation shaft to the third rotation shaft. The third rotation shaft drives the driven spur gear through the driving spur gear and the connection belt. Since the driving spur gear and the driven spur gear are driven by the connection belt, the driving spur gear and the driven spur gear are not affected by a translational motion of the side conveyor belt.

In some embodiment of the present disclosure, the insertion container is provided with a driving assembly for driving the transmission assembly to rotate, the driving assembly includes an electric motor disposed on the insertion container, and a driving bevel gear meshed with one of the transition bevel gears is disposed on an output shaft of the electric motor.

In some embodiment of the present disclosure, each of the pushing assemblies is a plurality of pneumatic cylinders fixed on the insertion container, two pneumatic cylinders are disposed on each of two sides of the insertion container, and a piston rod protruding from each of the pneumatic cylinders is fixedly connected to one of the movable brackets.

In some embodiment of the present disclosure, each of the movable brackets is connected to the insertion container through a guide assembly, and each of the guide assemblies includes a plurality of guide rods fixed on one of the movable brackets and includes a plurality of guide holes on the insertion container for insertion of the guide rods.

In some embodiment of the present disclosure, a tensioner pulley is arranged between each of the driven spur gears and a corresponding one of the driving spur gears, and each of the connection belts surrounds one of the tensioner pulleys to keep the connection belt tensioned.

Advantages of the present disclosure are:

1. The two side conveyor belts of the present disclosure can clamp or loosen the silicon wafers, and at the same time maintain the same linear speed as the bottom conveyor belt.

2. The transmission assembly of the present disclosure is not affected by a translational motion of the side conveyor belt.

### BRIEF DESCRIPTION OF DRAWINGS

FIG. 1 is a schematic view illustrating a structure of the present disclosure.

FIG. 2 is a schematic view illustrating a transmission structure of a driving spur gear and a driven spur gear.

LIST OF REFERENCE SIGNS

| | | |
|---|---|---|
| 1: Insertion container; | 2: Bottom conveyor belt; | 3: Side conveyor belts; |
| 4: Transmission assembly; | 5: Driving assembly; | 6: Pushing assembly; |
| 7: Movable bracket; | | |
| 4.1: First rotation shaft; | 4.2: Second rotation shaft; | 4.3: Transition bevel gear; |
| 4.4: Driven spur gears; | 4.5: Third rotation shaft; | 4.6 Driven bevel gear; |
| 4.7: Driven bevel gear; | 4.8: Connection belt; | 4.9: Tensioner pulley; |
| 5.1: Electric motor; | 5.2: Driving bevel gear; | 6.1: Protruding piston rod. |

### DETAILED DESCRIPTION OF EMBODIMENTS

The technical solutions of the present disclosure are clearly and completely described below with reference to specific embodiments and in conjunction with the accompanying drawings.

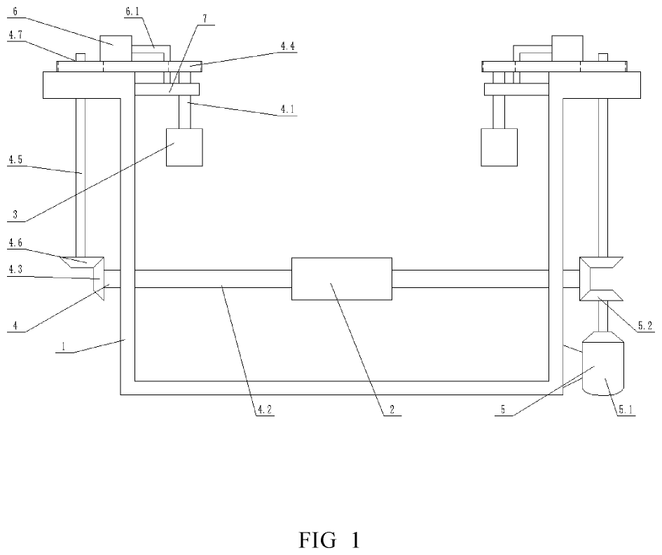

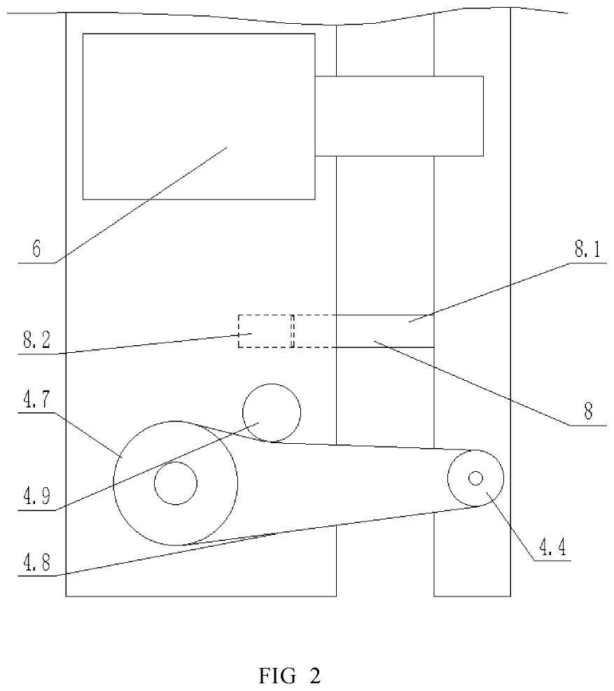

First Embodiment: As shown in FIGS. 1 and 2, a three-side conveyor equipment for silicon wafers includes an insertion container 1. A bottom conveyor belt 2 and two side conveyor belts 3 are arranged in the insertion container 1. The side conveyor belts 3 are arranged opposite to each other above the bottom conveyor belt 2. The bottom conveyor belt 2 is connected to the side conveyor belts 3 through a transmission assembly 4. The transmission assembly 4 includes a first rotation shaft 4.1 disposed on each of the side conveyor belts 3 and includes a second rotation shaft 4.2 disposed on the bottom conveyor belt 2. A transition bevel gear 4.3 is disposed at each of two ends of the second rotation shaft 4.2. A driven spur gear 4.4 is disposed on each of the first rotation shafts 4.1. Two third rotation shafts 4.5 are arranged on the insertion container 1. A driven bevel gear 4.6 is meshed with each of the transitional bevel gears 4.3 and is disposed at a bottom of each of the third rotation shafts 4.5. A driving spur gear 4.7 is disposed at a top of each of the third rotation shafts 4.5, and each of the driving spur gears 4.7 is connected to one of the driven spur gears 4.4 by a connection belt 4.8. A tensioner pulley 4.9 is arranged between each of the driven spur gears 4.4 and a corresponding one of the driving spur gears 4.7, and each of the connection belts 4.8 surrounds one of the tensioner pulleys 4.9. A linear speed of the bottom conveyor belt 2 is consistent with a linear speed of each of the side conveyor belts 3. A driving assembly 5 for driving the transmission assembly 4 to rotate is disposed on the insertion container 1. The driving assembly 5 includes an electric motor 5.1 disposed on the insertion container 1, and a driving bevel gear 5.2 meshed with one of the transition bevel gears 4.3 is disposed on an output shaft of the electric motor 5.1. Each of the side conveyor belts 3 is arranged on a movable bracket 7 that drives the side conveyor belt 3 to clamp or loosen. The insertion container 1 is provided with two pushing assemblies 6 that respectively push the two movable brackets 7 to move. Each of the pushing assemblies 6 is a plurality of pneumatic cylinders 6 fixed on the insertion container 1. In one embodiment, there are two pneumatic cylinders 6 disposed on each of two sides. A protruding piston rod 6.1 of each of the pneumatic cylinders 6 is fixedly connected to one of the movable brackets 7. Each of the movable brackets 7 is connected to the insertion container 1 through a guide assembly 8, and each of the guide assemblies includes a plurality of guide rods 8.1 fixed on one of the movable brackets 7 and includes a plurality of guide holes 8.2 on the insertion container 1 for insertion of the guide rods 8.1.

During operation, the silicon wafer is placed on the bottom conveyor belt 2, the pneumatic cylinder pushes the movable bracket 7, and the movable brackets 7 drive the side conveyor belts 3 to move, so that the side conveyor belt 3 clamps the silicon wafer, the connection belt 4.8 tightens, and the electric motor 5.1 drives the driving bevel gear 5.2 to rotate to drive the transition bevel gear 4.3 and the driven bevel gear 4.6. Thus, the second rotation shaft 4.2 and the third rotation shaft 4.5 are driven to rotate, and the driving spur gear 4.7 on the third rotation shaft 4.5 rotates, the driven spur gear 4.4 is driven to rotate by the connection belt 4.8, the first rotation shaft 4.1 rotates, and the bottom conveyor belt 2 and the two side conveyor belts 3 convey at the same linear speed.

The above embodiments are only some of the embodiments of the present disclosure, but are not all of them. Based on the embodiments of the present disclosure, all other embodiments obtained by persons of ordinary skill in the art without making creative efforts are deemed to fall within the protection scope of the present disclosure.

What is claimed is:

1. A three-side conveyor equipment for silicon wafers, comprising: an insertion container, wherein a bottom conveyor belt and two side conveyor belts are disposed in the insertion container, the two side conveyor belts are arranged opposite to each other above the bottom conveyor belt, the bottom conveyor belt is connected to the side conveyor belts through a transmission assembly, a linear speed of the bottom conveyor belt is same as a linear speed of each of the side conveyor belts, each of the side conveyor belts is arranged on a movable bracket which drives the side conveyor belt to clamp or loosen, and the insertion container is provided with two pushing assemblies that respectively push the two movable brackets to move.

2. The three-side conveyor equipment for the silicon wafers according to claim 1, wherein the transmission assembly comprises a first rotation shaft disposed on each of the side conveyor belts and a second rotation shaft disposed on the bottom conveyor belt, a transitional bevel gear is disposed at each of two ends of the second rotation shaft, a driven spur gear is disposed on each of the first rotation shafts, two third rotation shafts are arranged on the insertion container, a driven bevel gear is meshed with each of the transitional bevel gears and is disposed at a bottom of each of the third rotation shafts, a driving spur gear is disposed at a top of each of the third rotation shafts, and each of the driving spur gears is connected to a corresponding one of the driven spur gears by a connection belt.

3. The three-side conveyor equipment for the silicon wafers according to claim 2, wherein the insertion container is provided with a driving assembly for driving the transmission assembly to rotate, the driving assembly comprises an electric motor disposed on the insertion container, and a driving bevel gear meshed with one of the transition bevel gears is disposed on an output shaft of the electric motor.

4. The three-side conveyor equipment for the silicon wafers according to claim 1, wherein each of the pushing assemblies is a plurality of pneumatic cylinders fixed on the insertion container, and a piston rod protruding from each of the pneumatic cylinders is fixedly connected to one of the movable brackets.

5. The three-side conveyor equipment for the silicon wafers according to claim 1, wherein each of the movable brackets is connected to the insertion container through a guide assembly, and each of the guide assemblies comprises a plurality of guide rods fixed on one of the movable brackets and comprises a plurality of guide holes on the insertion container for insertion of the guide rods.

6. The three-side conveyor equipment for the silicon wafers according to claim 2, wherein a tensioner pulley is arranged between each of the driven spur gears and a corresponding one of the driving spur gears, and each of the connection belts surrounds one of the tensioner pulleys.
